(19) United States
(12) Patent Application Publication
(10) Pub. No.: US 2026/0231611 A1
(43) Pub. Date: Aug. 6, 2026

(54) DISPLAY DEVICE AND ELECTRONIC DEVICE INCLUDING THE SAME

(71) Applicant: Samsung Display Co., Ltd., Yongin-si, Gyeonggi-do (KR)

(72) Inventors: KYOUNG SEOK SON, Yongin-si (KR); EUNHYE KO, Yongin-si (KR); SEUNGHUN LEE, Yongin-si (KR); JAEHWAN CHU, Yongin-si (KR)

(21) Appl. No.: 19/287,635

(22) Filed: Jul. 31, 2025

(30) Foreign Application Priority Data
Feb. 3, 2025 (KR) 10-2025-0012968

(51) Int. Cl. H10K 59/121; H10D 30/67; H10D 86/40; H10D 86/60; H10K 59/131; H10K 102/00

(52) U.S. Cl. CPC H10K 59/1213; H10D 30/6737; H10K 59/131; H10D 30/6732; H10D 86/423; H10D 86/441; H10D 86/60; H10K 2102/351

(57) ABSTRACT

A display device includes: a substrate; a first conductive pattern on the substrate; a first gate electrode on the first conductive pattern; a second conductive pattern on the first gate electrode; a semiconductor pattern on the second conductive pattern, extending along a hole area penetrating the first gate electrode and the second conductive pattern in a first direction, which is a thickness direction, and electrically connected to the first conductive pattern and the second conductive pattern; a metal oxide pattern between the first gate electrode and the semiconductor pattern and insulating between the first gate electrode and the semiconductor pattern; and a second gate electrode on the semiconductor pattern, extending along the hole area, and electrically connected to the first gate electrode.

### CROSS-REFERENCE TO RELATED APPLICATION

The present application claims priority to and the benefit of Korean Patent Application No. 10-2025-0012968, filed on Feb. 3, 2025, in the Korean Intellectual Property Office, the entire disclosure of which is incorporated herein by reference.

### BACKGROUND

### 1. Field

Aspects of some embodiments of the present disclosure relate to a display device and an electronic device including the display device.

### 2. Description of the Related Art

As various portable electronic devices such as mobile communication terminals and notebook computers are developed, consumer demand for display devices that may be applied to them is increasing. Display devices include, for example, liquid crystal display devices, plasma display panels, and organic light-emitting diode display devices. Among these display devices, research on micro-OLEDs, which have various characteristics such as advancement in mass production technology, ease of driving means, low power consumption, high definition, and large screen implementation, is continuing.

Micro OLEDs may have characteristics such as being able to have high definition display devices compared to existing OLEDs, but they may have a challenge of requiring high integration of transistors, etc. To solve this challenge, it may be desirable to relatively reduce the diameter of holes, etc. when forming holes, etc.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the display device. For example, aspects of some embodiments of the present disclosure relate to the display device that provides visual information and the electronic device including the display device.

Aspects of some embodiments include a display device that may be implemented with high pixels.

Aspects of some embodiments include an electronic device including the display device.

A display device according to some embodiments of the present disclosure includes a substrate, a first conductive pattern on the substrate, a first gate electrode on the first conductive pattern, a second conductive pattern on the first gate electrode, a semiconductor pattern on the second conductive pattern, extending along a hole area penetrating the first gate electrode and the second conductive pattern in a first direction, which is a thickness direction, and electrically connected to the first conductive pattern and the second conductive pattern, a metal oxide pattern between the first gate electrode and the semiconductor pattern and insulating between the first gate electrode and the semiconductor pattern, and a second gate electrode on the semiconductor pattern, extending along the hole area, and electrically connected to the first gate electrode.

According to some embodiments, the display device may further include a first insulating layer that insulates the first conductive pattern and the first gate electrode and a second insulating layer that insulates the first gate electrode and the second conductive pattern.

According to some embodiments, a thickness of each of the first insulating layer and the second insulating layer between the first gate electrode and the first conductive pattern may be 1 nm to 1 μm.

According to some embodiments, a thickness of the metal oxide pattern in a second direction intersecting the first direction may be 1 nm to 1 μm.

According to some embodiments, the hole area may expose an upper surface of the first conductive pattern.

According to some embodiments, the second conductive pattern may include a conductive oxide.

According to some embodiments, the first gate electrode may include at least one selected from a group including aluminum and titanium.

According to some embodiments, the semiconductor pattern may include an oxide semiconductor.

A display device according to some embodiments of the present disclosure includes a substrate, a first conductive pattern on the substrate, a first gate electrode on the first conductive pattern and electrically connected to the first conductive pattern, a second conductive pattern on the first gate electrode, a semiconductor pattern on the second conductive pattern, extending along a hole area penetrating the first gate electrode and the second conductive pattern in a first direction which is a thickness direction, and electrically connected to the first conductive pattern and the second conductive pattern, a metal oxide pattern between the first gate electrode and the semiconductor pattern and insulating between the first gate electrode and the semiconductor pattern, and a second gate electrode on the semiconductor pattern and extending along the hole area.

According to some embodiments, the display device may further include an insulating layer insulating the first gate electrode from the second conductive pattern.

According to some embodiments, a thickness of the insulating layer between the first gate electrode and the first conductive pattern may be in a range of 1 nm to 1 μm.

According to some embodiments, a thickness of the metal oxide pattern in a second direction intersecting the first direction may be 1 nm to 1 μm.

According to some embodiments, the hole area may expose an upper surface of the first conductive pattern.

According to some embodiments, the second conductive pattern may include a conductive oxide.

According to some embodiments, the first gate electrode may include at least one selected from a group including aluminum and titanium.

According to some embodiments, the semiconductor pattern may include an oxide semiconductor.

A method of manufacturing a display device according to some embodiments of the present disclosure includes depositing a first conductive pattern, a first insulating layer, a preliminary first gate electrode, a second insulating layer, and a preliminary second conductive pattern sequentially on a substrate, patterning the preliminary second conductive pattern to form a second conductive pattern and exposing an upper surface of the second insulating layer, forming a first gate electrode by simultaneously patterning the second insulating layer, the preliminary first gate electrode, and the first insulating layer and forming a hole area exposing an upper surface of the first conductive pattern, forming a metal oxide pattern by oxidizing the first gate electrode exposed by the hole area, forming a semiconductor pattern on the hole area, and forming a second gate electrode on the semiconductor pattern.

According to some embodiments, the oxidizing of the first gate electrode may include thermal oxidation or plasma oxidation.

According to some embodiments, the method may further include after forming the second gate electrode, electrically connecting the first gate electrode and the second gate electrode.

An electronic device according to some embodiments of the present disclosure includes a display device and a processor configured to drive the display device, and wherein the display device includes a substrate, a first conductive pattern on the substrate, a first gate electrode on the first conductive pattern, a second conductive pattern on the first gate electrode, a semiconductor pattern on the second conductive pattern, extending along a hole area penetrating the first gate electrode and the second conductive pattern in a first direction, which is a thickness direction, and electrically connected to the first conductive pattern and the second conductive pattern, a metal oxide pattern between the first gate electrode and the semiconductor pattern and insulating between the first gate electrode and the semiconductor pattern, and a second gate electrode on the semiconductor pattern, extending along the hole area, and electrically connected to the first gate electrode.

A display device according to some embodiments of the present disclosure may include a substrate, a first conductive pattern on the substrate, a first gate electrode on the first conductive pattern, a second conductive pattern on the first gate electrode, a semiconductor pattern on the second conductive pattern, extending along a hole area penetrating the first gate electrode and the second conductive pattern in a first direction, which is a thickness direction, and electrically connected to the first conductive pattern and the second conductive pattern, a metal oxide pattern between the first gate electrode and the semiconductor pattern and insulating between the first gate electrode and the semiconductor pattern, and a second gate electrode on the semiconductor pattern, extending along the hole area, and electrically connected to the first gate electrode.

Because the semiconductor pattern is arranged in a thickness direction along the hole region, integration density of the transistor may be relatively improved, and current flow may be well controlled through a dual gate structure. In addition, since the metal oxide pattern is located between the semiconductor pattern and the first gate electrode, it may block foreign substances (e.g., hydrogen) from entering the semiconductor pattern and may also function as an insulating layer. As a result, control of the transistor may be facilitated, and integration density may be relatively increased, thereby relatively improving the display quality of the display device.

In addition, in a method of manufacturing the display device, even when using exposure equipment that emits light having a width of 1.5 μm to 2.0 μm (or about 1.5 μm to about 2.0 μm), a diameter of the hole may be relatively reduced to 0.8 μm (or about 0.8 μm) or less. Accordingly, the second hole having the second diameter may be formed even without replacing the exposure equipment, etc. with one having a smaller width.

### BRIEF DESCRIPTION OF THE DRAWINGS

The accompanying drawings, which are included to provide a further understanding of embodiments according to the present disclosure and are incorporated in and constitute a part of this specification, illustrate aspects of some embodiments of the present together with the description.

FIG. 1 is a perspective view of a display device according to some embodiments of the present disclosure.

FIG. 2 is a cross-sectional view showing further details of the display device of FIG. 1 according to some embodiments.

FIG. 3 is a cross-sectional view illustrating further details of the display panel of FIG. 2 according to some embodiments.

FIGS. 4, 5, 6, 7, 8, 9, 10, 11, 12, 13, and 14 are views showing aspects of a method of manufacturing the display panel of FIG. 3.

FIG. 15 is a cross-sectional view aspects of the display panel of FIG. 2 according to some embodiments.

FIG. 16 is a block diagram showing an electronic device according to some embodiments of the present disclosure.

FIG. 17 is schematic diagrams showing various embodiments of the electronic device of FIG. 16.

### DETAILED DESCRIPTION

Regarding embodiments of the present disclosure disclosed in this text, specific structural and functional descriptions are merely illustrative for a purpose of explaining the embodiments of the present disclosure, and the embodiments of the present disclosure may be implemented in various forms and should not be construed as limited to the embodiments described in.

Because embodiments according to the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as first, second, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting of embodiments according to the present disclosure. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

Unless otherwise defined, all terms (including technical and scientific terms) used herein have a same meaning as commonly understood by one of ordinary skill in the art to which embodiments according to the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and some redundant descriptions of same components may be omitted.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

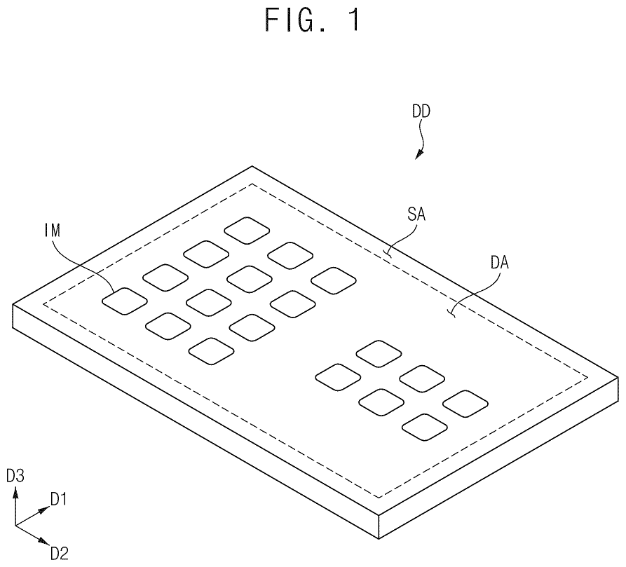

FIG. 1 is a perspective view showing a display device according to some embodiments of the present disclosure.

Referring to FIG. 1, a display device DD may include a display area DA and a peripheral area SA. The display area DA may be at least partially surrounded by the peripheral area SA. According to some embodiments, the peripheral area SA may surround (e.g., in a periphery or outside a footprint of) the display area DA.

The display area DA may be an area capable of generating light. The display area DA may be an area capable of adjusting a transmittance of light provided from an external light source to display images. The peripheral area SA may be an area that does not display images. However, embodiments of the present disclosure are not necessarily limited thereto. At least a portion of the peripheral area SA may also display images.

The display area DA may display a plurality of images IM. Through the plurality of images IM, users may receive information from the display device DD.

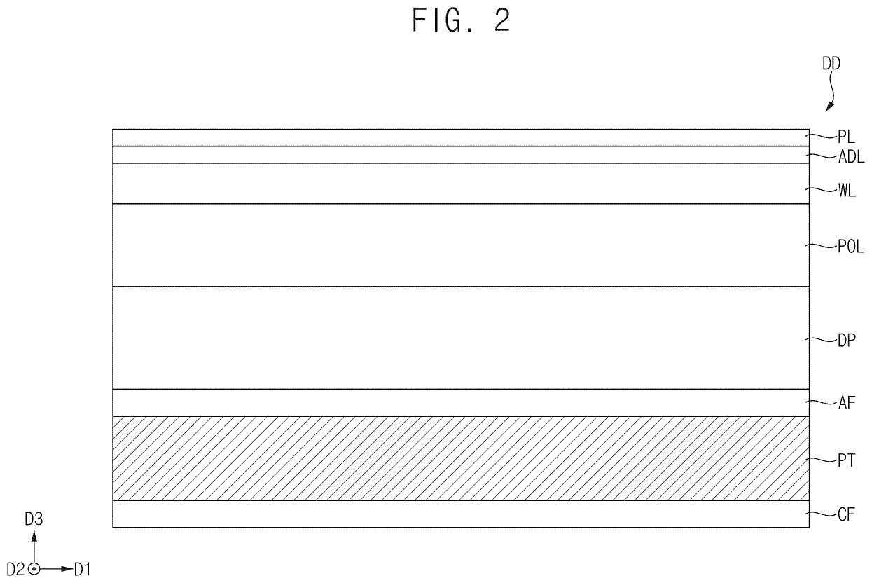

FIG. 2 is a cross-sectional view showing aspects of the display device of FIG. 1 according to some embodiments.

Referring to FIGS. 1 and 2, the display device DD may include a cover film CF, a plate PT, an adhesive film AF, a display panel DP, a polymer layer POL, a window layer WL, an adhesive layer ADL, and a protective film PL.

The cover film CF may be located on a rear surface of the display device DD. The cover film CF may cushion an impact received from an outside of the display device DD. The cover film CF may include at least one of sponge, foam, thermoplastic polyurethane, or polydimethylacrylamide. These may be used alone or in combination with each other. Optionally, the cover film CF may include a light-blocking material. Accordingly, the cover film CF may absorb light incident from a rear surface of the display device DD.

The plate PT may be located on the cover film CF. The plate PT may prevent the display panel DP from bending due to an external force. That is, the plate PT may maintain the display panel DP in a relatively flat state even when an external force is applied to the display device DD. The plate PT may include a material having rigidity. The plate PT may include a material having semi-rigidity. For example, the plate PT may include at least one of iron, chromium, carbon, nickel, silicon, manganese, or molybdenum. These may be used alone or in combination with each other. However, embodiments of the present disclosure are not necessarily limited thereto.

The adhesive film AF may be located on the plate PT. The adhesive film AF may attach the plate PT and the display panel DP. For example, the adhesive film AF may include at least one of a pressure-sensitive adhesive (PSA), an optical clear adhesive (OCA), or an optical clear resin (OCR). These may be used alone or in combination with each other. However, embodiments of the present disclosure are not necessarily limited thereto.

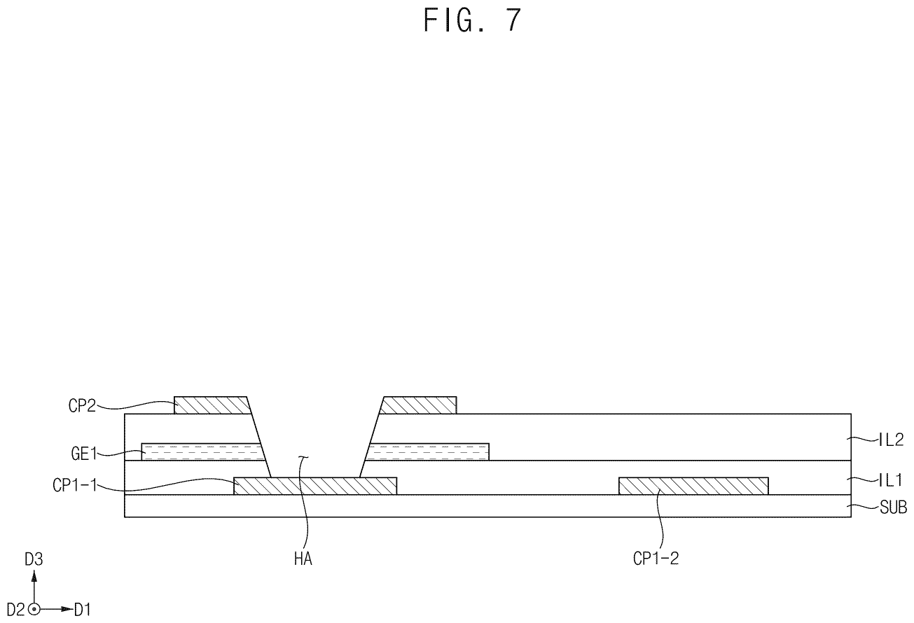

The display panel DP may be located on the adhesive film AF. The display panel DP may generate light in response to an input signal. Accordingly, the display panel DP may provide a visual image to a user of the display device DD. Descriptions regarding the display panel DP will be described in more detail later with reference to FIG. 7.

The polymer layer POL may be located on the display panel DP. The polymer layer POL may attach the display panel DP and the window layer WL. The polymer layer POL may support the window layer WL to prevent or reduce sagging. The polymer layer POL may protect the display panel DP from external impacts. The polymer layer POL may have a single-layer or multi-layer structure.

The window layer WL may be located on the polymer layer POL. The window layer WL may cover a front surface of the display device DD. The window layer WL may protect the display panel DP. The window layer WL may include a transparent (or substantially transparent) material. For example, the window layer WL may be made of glass or plastic. However, embodiments of the present disclosure are not necessarily limited thereto.

The adhesive layer ADL may be located on the window layer WL. The adhesive layer ADL may attach the window layer WL and the protective film PL. The adhesive layer ADL may include a transparent material. For example, the adhesive layer ADL may include at least one of a pressure-sensitive adhesive (PSA), an optical clear adhesive (OCA), or an optical clear resin (OCR). These may be used alone or in combination with each other. However, embodiments of the present disclosure are not necessarily limited thereto.

The protective film PL may be located on the adhesive layer ADL. The protective film PL may protect the window layer WL from external impacts. The protective film PL may protect the window layer WL from scratches. For example, the protective film PL may include a base layer or a hard coating layer. However, embodiments of the present disclosure are not necessarily limited thereto. The protective film PL may further include a low refractive index layer and/or a fingerprint-resistant layer.

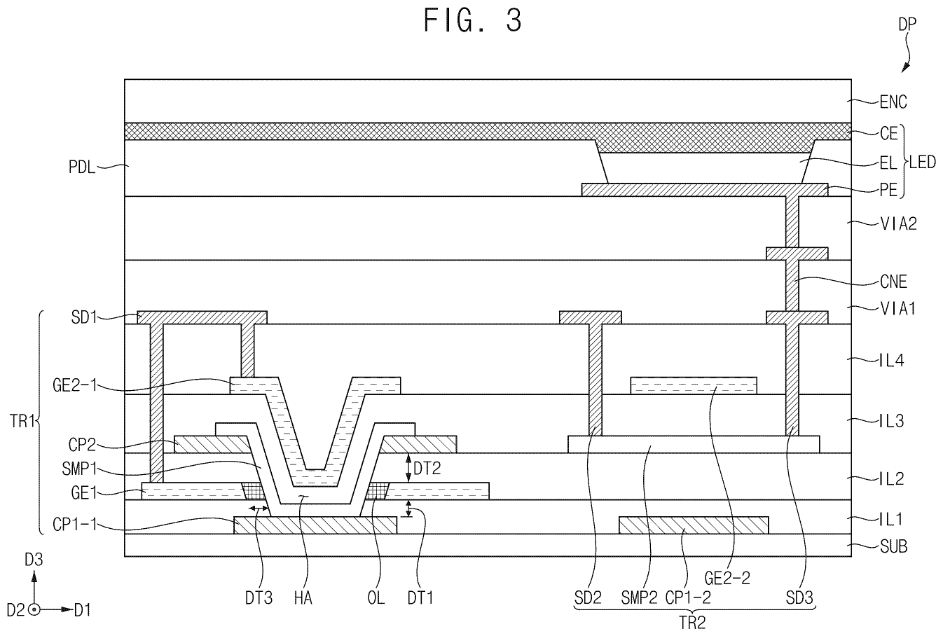

FIG. 3 is a cross-sectional view showing aspects of the display panel of FIG. 2 according to some embodiments.

Referring to FIGS. 2 and 3, the display panel DP may include a substrate SUB, first, second, third, and fourth insulating layers IL1, IL2, IL3, and IL4, a first-second conductive pattern CP1-2, a first transistor TR1, a second transistor TR2, first, second, and third interlayer conductive layers SD1, SD2, and SD3, a first via layer VIA1, a connection electrode CNE, a second via layer VIA2, a light-emitting diode LED, a pixel defining layer PDL, and a encapsulation layer ENC.

The first transistor TR1 may include a first gate electrode GE1, a second-first gate electrode GE2-1, a first semiconductor pattern SMP1, a first-first conductive pattern CP1-1, and a second conductive pattern CP2. The second transistor TR2 may include a second semiconductor pattern SMP2 and a second-second gate electrode GE2-2. The light-emitting diode LED may include a pixel electrode PE, an emission layer EL, and a common electrode CE.

The substrate SUB may include a glass substrate, a metal substrate, a plastic substrate, etc. However, the embodiments of the present disclosure are not necessarily limited thereto, and the substrate SUB may be an inorganic layer, an organic layer, or a composite material layer.

The first-first conductive pattern CP1-1 and the first-second conductive pattern CP1-2 may be located on the substrate SUB. The first-first conductive pattern CP1-1 and the first-second conductive pattern CP1-2 may be spaced apart from each other in the first direction D1. The first-first conductive pattern CP1-1 may be a source/drain electrode of the first transistor TR1.

For example, each of the first-first conductive pattern CP1-1 and the first-second conductive pattern CP1-2 may include a metal, an alloy, a metal nitride, a conductive metal oxide, a transparent conductive material, etc. These may be used alone or in combination with each other. However, the embodiments of the present disclosure are not necessarily limited thereto.

Although in FIG. 3, the first-first conductive pattern CP1-1 and the first-second conductive pattern CP1-2 are shown as being spaced apart from each other, the embodiments of the present disclosure are not necessarily limited thereto. The first-first conductive pattern CP1-1 and the first-second conductive pattern CP1-2 may be electrically connected to each other. Each of the first-first conductive pattern CP1-1 and the first-second conductive pattern CP1-2 may prevent light incident in the third direction D3 from outside the display panel DP from reaching the first semiconductor pattern SMP1 of the first transistor TR1 and the second semiconductor pattern SMP2 of the second transistor TR2. That is, the first-first conductive pattern CP1-1 and the first-second conductive pattern CP1-2 may be a light-blocking layer of the first transistor TR1 and the second transistor TR2, respectively.

The first insulating layer IL1 may be located on the substrate SUB. For example, the first insulating layer IL1 may cover the first-first conductive pattern CP1-1 and the first-second conductive pattern CP1-2, and may be located on the substrate SUB. The first insulating layer IL1 may prevent impurities such as oxygen and moisture from penetrating from under the substrate SUB to an upper surface of the substrate SUB. The first insulating layer IL1 may include an inorganic insulating material. The first insulating layer IL1 may also be referred to as a buffer layer.

The first gate electrode GE1 may be located on the first insulating layer IL1. The first gate electrode GE1 may be a back gate electrode of the first transistor TR1. The first gate electrode GE1 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. However, the embodiments of the present disclosure are not necessarily limited thereto.

According to some embodiments, the first-first conductive pattern CP1-1 and the first gate electrode GE1 may be spaced apart by a first distance DT1 in a cross-sectional view. For example, the first-first conductive pattern CP1-1 and the first gate electrode GE1 may be spaced apart by the first distance DT1 in the third direction D3. The first distance DT1 may be 1 nm or more and 1 μm or less (about 1 nm or more and about 1 μm or less). Preferably, the first distance DT1 may be 1 nm or more and 500 nm or less (or about 1 nm or more and about 500 nm or less). By satisfying this range, a current flow of the first transistor TR1 may be stably controlled.

The second insulating layer IL2 may be located on the first insulating layer IL1. For example, the second insulating layer IL2 may cover the first gate electrode GE1 and may be located on the first insulating layer IL1. The second insulating layer IL2 may include a same (or substantially a same material) as the first insulating layer IL1. However, the embodiments of the present disclosure are not necessarily limited thereto.

The second conductive pattern CP2 may be located on the second insulating layer IL2. The second conductive pattern CP2 may be a source/drain electrode of the first transistor TR1. For example, the second conductive pattern CP2 may include a same (or substantially a same) material as the first-first conductive pattern CP1-1. However, the embodiments of the present disclosure are not necessarily limited thereto.

According to some embodiments, the first gate electrode GE1 and the second conductive pattern CP2 may be spaced apart by a second distance DT2 in a cross-sectional view. For example, the first gate electrode GE1 and the second conductive pattern CP2 may be spaced apart by the second distance DT2 in the third direction D3. The second distance DT2 may be 1 nm or more and 1 μm or less (or about 1 nm or more and about 1 μm or less). Preferably, the second distance DT2 may be 1 nm or more and 500 nm or less (or about 1 nm or more and about 500 nm or less). By satisfying this range, a current flow of the first transistor TR1 may be stably controlled.

A hole area HA may be defined in the first transistor TR1. The hole area HA may penetrate through the second conductive pattern CP2, the second insulating layer IL2, the first gate electrode GE1, and the first insulating layer IL1 in a direction opposite to the third direction D3 (i.e., in the thickness direction). The hole area HA may expose an upper surface of the first-first conductive pattern CP1-1 by penetrating through the second conductive pattern CP2, the second insulating layer IL2, the first gate electrode GE1, and the first insulating layer IL1 in the opposite direction of the third direction D3.

The first semiconductor pattern SMP1 and the second semiconductor pattern SMP2 may be located on the second insulating layer IL2. For example, the first semiconductor pattern SMP1 may be located on the second conductive pattern CP2 and may extend in a direction opposite to the third direction D3 along the hole area HA. In addition, the first semiconductor pattern SMP1 may contact the first-first conductive pattern CP1-1 exposed by the hole area HA. The first semiconductor pattern SMP1 may be electrically connected to the first-first conductive pattern CP1-1 and the second conductive pattern CP2. Accordingly, the first-first conductive pattern CP1-1 and the second conductive pattern CP2 may be electrically connected.

Each of the first semiconductor pattern SMP1 and the second semiconductor pattern SMP2 may include a source region, a drain region, and a channel region positioned between the source region and the drain region. The channel region of the first semiconductor pattern SMP1 may overlap the first gate electrode GE1 in a plan view perpendicular to the first direction D1. That is, the first gate electrode GE1 may control a current flow of the first semiconductor pattern SMP1. At least a portion of the channel region of the second semiconductor pattern SMP2 may overlap the first-second conductive pattern CP1-2 in a plan view.

According to some embodiments, the first semiconductor pattern SMP1 and the second semiconductor pattern SMP2 may include an oxide semiconductor. That is, the first transistor TR1 and the second transistor TR2 may be N-type transistors. However, the embodiments of the present disclosure are not necessarily limited thereto. The first transistor TR1 and the second transistor TR2 may also be P-type transistors.

According to some embodiments, a metal oxide pattern OL may be located between the first semiconductor pattern SMP1 and the first gate electrode GE1. The metal oxide pattern OL may be a pattern formed by oxidation of the first gate electrode GE1. The metal oxide pattern OL may block some impurities (e.g., hydrogen) from migrating to the first semiconductor pattern SMP1 through the second insulating layer IL2. The metal oxide pattern OL may electrically insulate the first semiconductor pattern SMP1 from the first gate electrode GE1 through the second insulating layer IL2. By arranging the metal oxide pattern OL between the first semiconductor pattern SMP1 and the first gate electrode GE1, electron mobility of the first transistor TR1 may be relatively improved.

For example, the metal oxide pattern OL may include a conductive oxide. The conductive oxide may include ITO, IZO, ITZO, and In₂O₃. These may be used alone or in combination with each other. However, the embodiments of the present disclosure are not necessarily limited thereto.

According to some embodiments, the first gate electrode GE1 and the first semiconductor pattern SMP1 may be spaced apart from each other by a third distance DT3 in the first direction D1. That is, a thickness of the metal oxide pattern OL in the first direction D1 may correspond to a size of the third distance DT3. The third distance DT3 may be 1 nm or more and 1 μm or less (or about 1 nm or more and about 1 μm or less). Preferably, the third distance DT3 may be 1 nm or more and 500 nm or less (or about 1 nm or more and about 500 nm or less). By satisfying this range, the first gate electrode GE1 may stably control a current flow of the first transistor TR1.

Because the first and second semiconductor patterns SMP1 and SMP2 are located in the thickness direction along the hole area, an integration degree of the transistors included in the display device DD may be relatively improved, and a current flow may be well controlled by a dual gate structure. In addition, by arranging the metal oxide pattern OL between the first semiconductor pattern SMP1 and the first gate electrode GE1, foreign substances (e.g., hydrogen) flowing into the first semiconductor pattern SMP1 may be blocked, and the pattern may function as an insulating layer.

The third insulating layer IL3 may be located on the second insulating layer IL2. For example, the third insulating layer IL3 may cover the second conductive pattern CP2, the first semiconductor pattern SMP1, and the second semiconductor pattern SMP2, and may be located on the second insulating layer IL2. The third insulating layer IL3 may include a same (or substantially a same) material as the first insulating layer IL1. However, the embodiments of the present disclosure are not necessarily limited thereto.

The second-first gate electrode GE2-1 and the second-second gate electrode GE2-2 may be located on the third insulating layer IL3. For example, the second-first gate electrode GE2-1 may overlap the channel region of the first semiconductor pattern SMP1 in a plan view, and the second-second gate electrode GE2-2 may overlap the channel region of the second semiconductor pattern SMP2 in a plan view.

The second-first gate electrode GE2-1 may extend in a direction opposite to the third direction D3 along the hole area HA. Accordingly, the second-first gate electrode GE2-1 may overlap the channel region of the first semiconductor pattern SMP1 in a plan view perpendicular to the first direction D1. That is, the first transistor TR1 may be a vertical gate transistor.

The fourth insulating layer IL4 may be located on the third insulating layer IL3. For example, the fourth insulating layer IL4 may cover the second-first gate pattern GE2-1 and the second-second gate pattern GE2-2, and may be located on the third insulating layer IL3. The fourth insulating layer IL4 may include a same (or substantially a same) material as the first insulating layer IL1. However, the embodiments of the present disclosure are not necessarily limited thereto.

The first, second, and third interlayer conductive layers SD1, SD2, and SD3 may be located on the fourth insulating layer IL4. For example, the first interlayer conductive layer SD1 may penetrate the fourth insulating layer IL4 to contact the second-first gate electrode GE2-1, and may also penetrate the second insulating layer IL2, the third insulating layer IL3, and the fourth insulating layer IL4 to contact the first gate electrode GE1. The second and third interlayer conductive layers SD2 and SD3 may respectively penetrate the third insulating layer IL3 and the fourth insulating layer IL4 to contact the second semiconductor pattern SMP2. Each of the second and third interlayer conductive layers SD2 and SD3 may be a source/drain electrode of the second transistor TR2.

According to some embodiments, the first interlayer conductive layer SD1 may electrically connect the first gate electrode GE1 and the second-first gate electrode GE2-1. As the first gate electrode GE1 and the second-first gate electrode GE2-1 are electrically connected via the first interlayer conductive layer SD1, an amount of current flowing through the channel region of the first semiconductor pattern SMP1 may increase. Furthermore, as a double gate electrode connecting the first gate electrode GE1 and the second-first gate electrode GE2-1 is located, the threshold voltage of the first transistor TR1 may be more easily controlled. For example, when the first gate electrode GE1 and the second-first gate electrode GE2-1 are electrically connected, the first transistor TR1 may be a switching transistor.

The first via layer VIA1 may be located on the fourth insulating layer IL4. For example, the first via layer VIA1 may cover the first, second, and third interlayer conductive layers SD1, SD2, and SD3, and may be located on the fourth insulating layer IL4. An upper surface of the first via layer VIA1 may be planar. The first via layer VIA1 may include an organic insulating material. According to some embodiments, the first via layer VIA1 may be formed only in the display area DA and a portion of the peripheral area SA adjacent to the display area DA.

The connection electrode CNE may be located on the first via layer VIA1. The connection electrode CNE may transmit a signal delivered from the second transistor TR2 to the light-emitting diode LED. The connection electrode CNE may include a metal, an alloy, a metal nitride, a conductive metal oxide, a transparent conductive material, etc. These may be used alone or in combination with each other. However, the embodiments of the present disclosure are not necessarily limited thereto.

The second via layer VIA2 may be located on the first via layer VIA1. For example, the second via layer VIA2 may cover the connection electrode CNE and may be located on the first via layer VIA1. An upper surface of the second via layer VIA2 may be planar. The second via layer VIA2 may include a same (or substantially a same) material as the first via layer VIA1.

The pixel electrode PE may be located on the second via layer VIA2. The pixel electrode PE may include a conductive material. The pixel electrode PE may be connected to the third interlayer conductive layer SD3 via the connection electrode CNE. Accordingly, the pixel electrode PE may be electrically connected to the second transistor TR2.

The pixel defining layer PDL may be located on the pixel electrode PE. For example, the pixel defining layer PDL may expose at least a portion of the pixel electrode PE. The pixel defining layer PDL may include an inorganic insulating material or an organic insulating material.

The emission layer EL may be located on the pixel electrode PE. According to some embodiments, the emission layer EL may be located within an opening defined by the pixel defining layer PDL. That is, the emission layer EL may be surrounded by the pixel defining layer PDL. According to some embodiments, the emission layer EL may also be located on the pixel defining layer PDL. The emission layer EL may include at least one of an organic light-emitting material or quantum dots. However, the embodiments of the present disclosure are not necessarily limited thereto.

The common electrode CE may be located on the emission layer EL. The common electrode CE may also be located on the pixel defining layer PDL. That is, the common electrode CE may be continuously arranged on the emission layer EL and the pixel defining layer PDL. The common electrode CE may include a conductive material. The emission layer EL may emit light based on a voltage difference between the pixel electrode PE and the common electrode CE.

The encapsulation layer ENC may cover an upper surface of the common electrode CE. The encapsulation layer ENC may include at least one organic encapsulation layer and at least one inorganic encapsulation layer. According to some embodiments, the organic encapsulation layer and the inorganic encapsulation layer may be alternately stacked. For example, the organic encapsulation layer may include a polymer cured material such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, titanium oxide, etc.

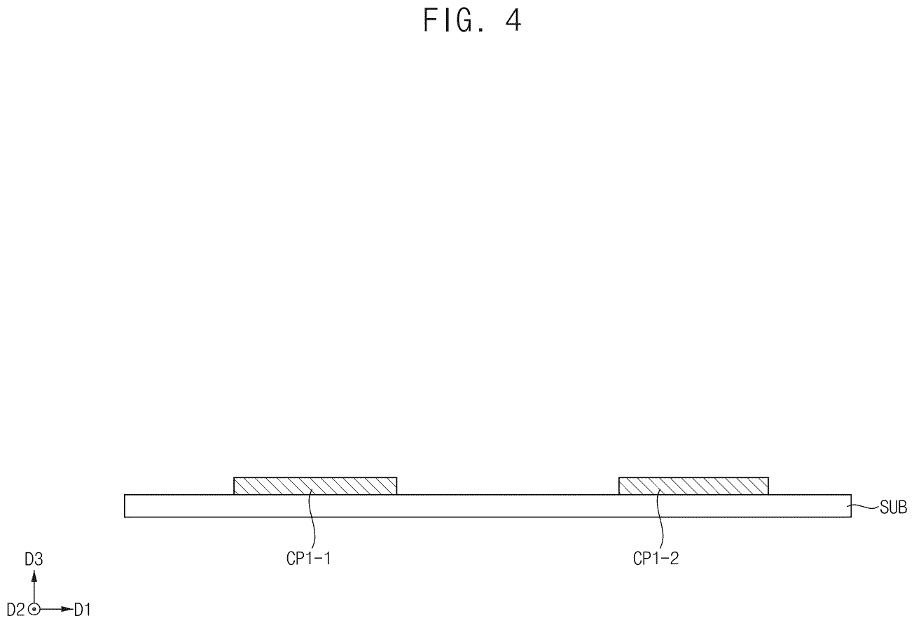

FIGS. 4, 5, 6, 7, 8, 9, 10, 11, 12, 13, and 14 are views showing aspects of a method of manufacturing the display panel of FIG. 3.

Referring to FIG. 4, the first-first conductive pattern CP1-1 and the first-second conductive pattern CP1-2 may be formed on the substrate SUB. The first-first conductive pattern CP1-1 and the first-second conductive pattern CP1-2 may be formed in a same process. The first-first conductive pattern CP1-1 and the first-second conductive pattern CP1-2 may be spaced apart from each other in the first direction D1. Although in FIG. 4 the first-first conductive pattern CP1-1 and the first-second conductive pattern CP1-2 are shown as being spaced apart, the embodiments of the present disclosure are not necessarily limited thereto. The first-first conductive pattern CP1-1 and the first-second conductive pattern CP1-2 may be electrically connected to each other.

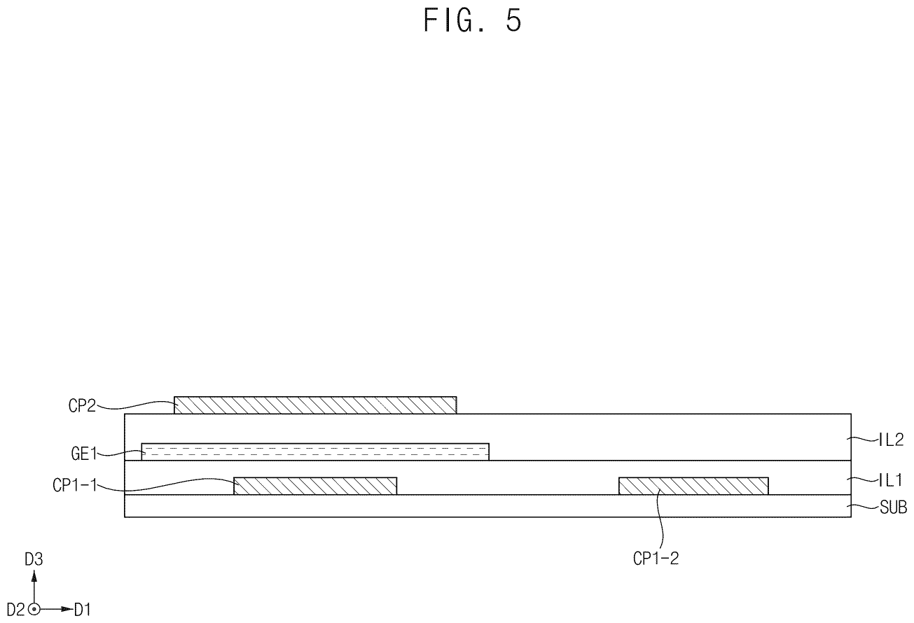

Referring further to FIG. 5, the first insulating layer IL1, the first gate electrode GE1, the second insulating layer IL2, and the second conductive pattern CP2 may be sequentially formed on the substrate SUB. The first-first conductive pattern CP1-1, the first gate electrode GE1, and the second conductive pattern CP2 may overlap in a plan view. However, the embodiments of the present disclosure are not necessarily limited thereto.

The first gate electrode GE1 may include a metal such as aluminum (Al), titanium (Ti), copper (Cu), molybdenum (Mo), tantalum (Ta), calcium (Ca), chromium (Cr), magnesium (Mg), or nickel (Ni). These may be used alone or in combination with each other. However, the embodiments of the present disclosure are not necessarily limited thereto.

The first-first conductive pattern CP1-1 and the second conductive pattern CP2 may include a conductive oxide such as ITO, IZO, ITZO, or In₂O₃. These may be used alone or in combination with each other. However, the embodiments of the present disclosure are not necessarily limited thereto.

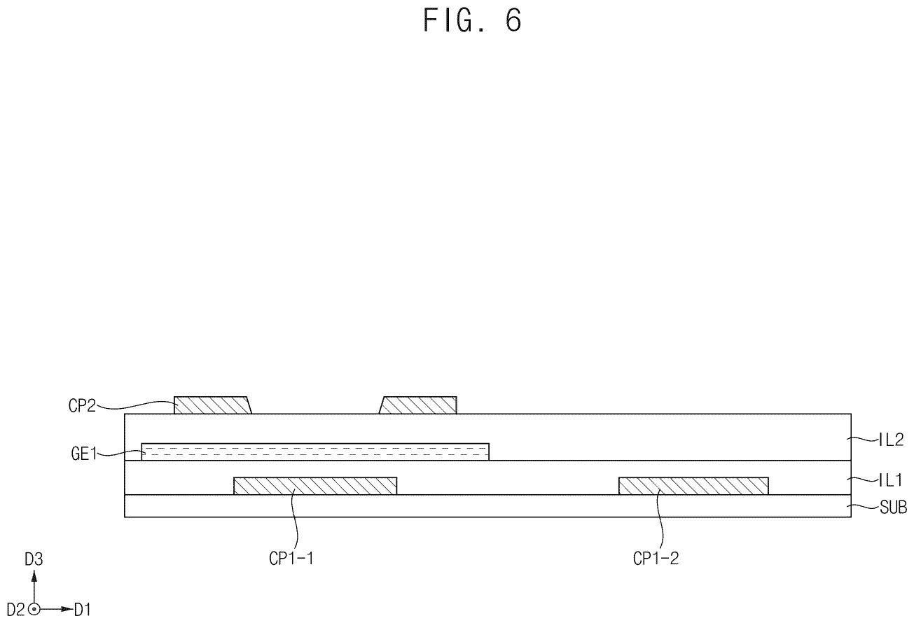

Referring further to FIG. 6, a portion of the second conductive pattern CP2 may be patterned by an etching process. As the second conductive pattern CP2 is patterned, an upper surface of the second insulating layer IL2, which overlapped the second conductive pattern CP2 in a plan view, may be exposed.

Referring further to FIG. 7, using the patterned second conductive pattern CP2 as a mask, an etching process may be sequentially performed on the second insulating layer IL2, the first gate electrode GE1, and the first insulating layer IL1. As the etching process proceeds, an upper surface of the first-first conductive pattern CP1-1 may be exposed. In addition, the second insulating layer IL2, the first gate electrode GE1, and the first insulating layer IL1 may be etched to form the hole area HA. That is, the hole area HA may extend in the third direction D3 and may expose the upper surface of the first-first conductive pattern CP1-1.

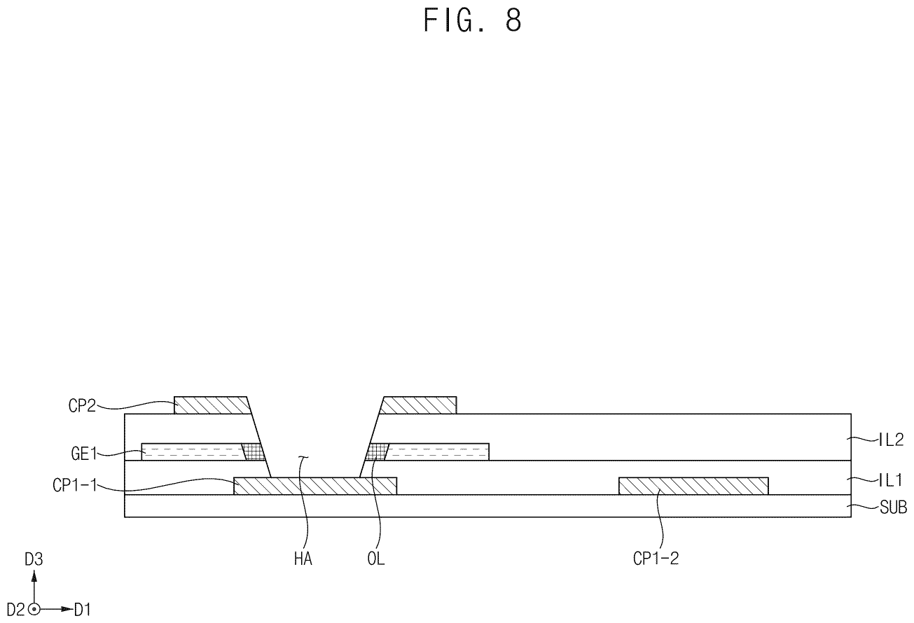

Referring further to FIG. 8, an oxidation process may be performed in the hole area HA. The oxidation process may be selectively performed in the hole area HA, but may also be performed over an entire upper surface of the second insulating layer IL2. By the oxidation process, a side surface of the first gate electrode GE1 exposed in the first direction D1 by the hole area HA may be oxidized. The oxidation process may be a thermal oxidation process or a plasma oxidation process. However, the embodiments of the present disclosure are not necessarily limited thereto.

Because the first-first conductive pattern CP1-1 and the second conductive pattern CP2 include a conductive oxide, the first-first conductive pattern CP1-1 and the second conductive pattern CP2 may not be further oxidized by the oxidation process. As a result, the oxidation process may be performed only on the side surface of the first gate electrode GE1 to form the metal oxide pattern OL. The metal oxide pattern OL may include aluminum oxide, titanium oxide, etc.

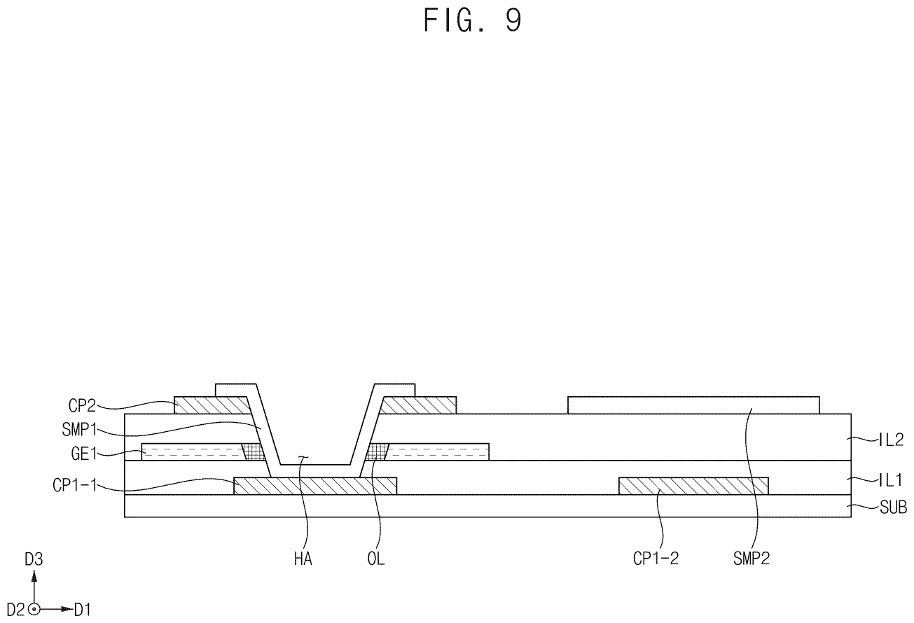

Referring further to FIG. 9, the first semiconductor pattern SMP1 and the second semiconductor pattern SMP2 may be formed on the second insulating layer IL2. The first semiconductor pattern SMP1 and the second semiconductor pattern SMP2 may be formed at the same time. For example, the first semiconductor pattern SMP1 may be formed to extend in a direction opposite to the third direction D3 along the hole area HA and may be formed to contact the first-first conductive pattern CP1-1 and the second conductive pattern CP2. The second semiconductor pattern SMP2 may be formed to at least partially overlap the first-second conductive pattern CP1-2 in a plan view.

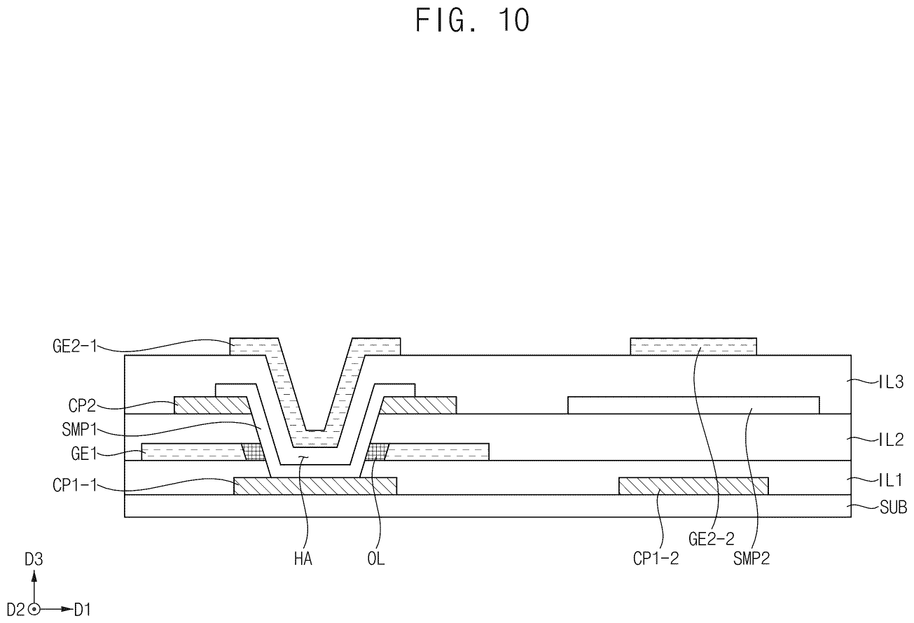

Referring further to FIG. 10, the third insulating layer IL3 may be formed on the second insulating layer IL2. The third insulating layer IL3 may be formed along a profile of the hole area HA. Accordingly, the third insulating layer IL3 may cover the second conductive pattern CP2, the first semiconductor pattern SMP1, and the second semiconductor pattern SMP2, and may be formed on the second insulating layer IL2.

The second-first gate electrode GE2-1 and the second-second gate electrode GE2-2 may be formed on the third insulating layer IL3. For example, the second-first gate electrode GE2-1 may overlap the first semiconductor pattern SMP1 in a plan view, and the second-second gate electrode GE2-2 may overlap the second semiconductor pattern SMP2 in a plan view. The second-first gate electrode GE2-1 may extend in a direction opposite to the third direction D3 in the hole area HA.

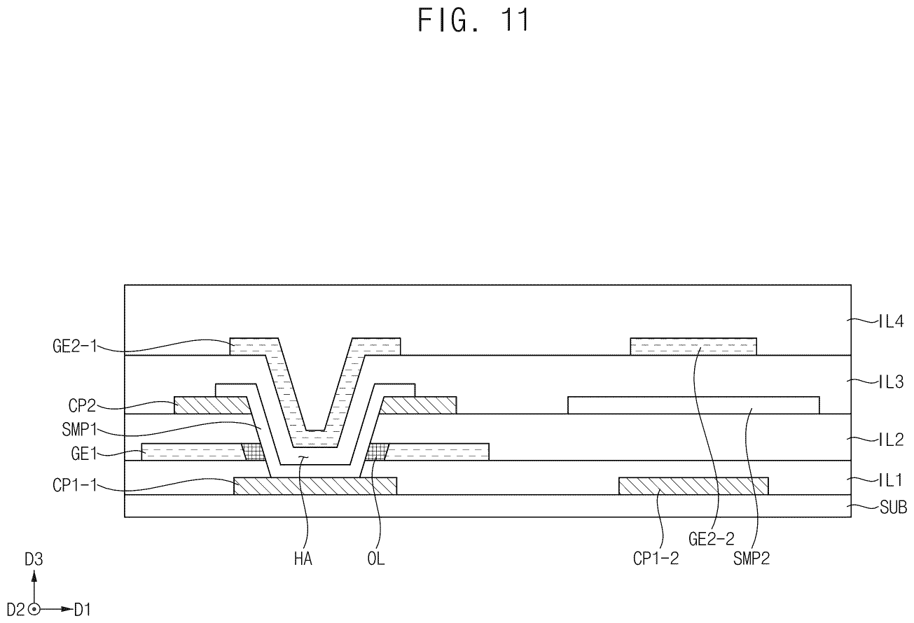

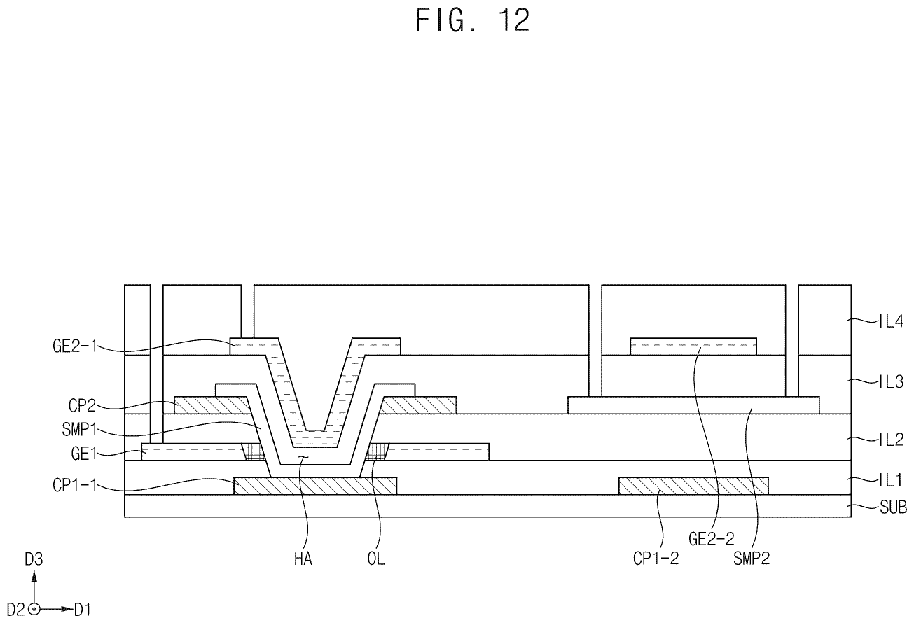

Referring further to FIGS. 11 and 12, the fourth insulating layer IL4 may be formed on the third insulating layer IL3. An upper surface of the fourth insulating layer IL4 may be patterned such that holes are formed in portions of the fourth insulating layer IL4. The holes may be formed to penetrate the second insulating layer IL2, the third insulating layer IL3, and/or the fourth insulating layer IL4. For example, each of the holes may expose an upper surface of the first gate electrode GE1, the second-first gate electrode GE2-1, or the second semiconductor pattern SMP2.

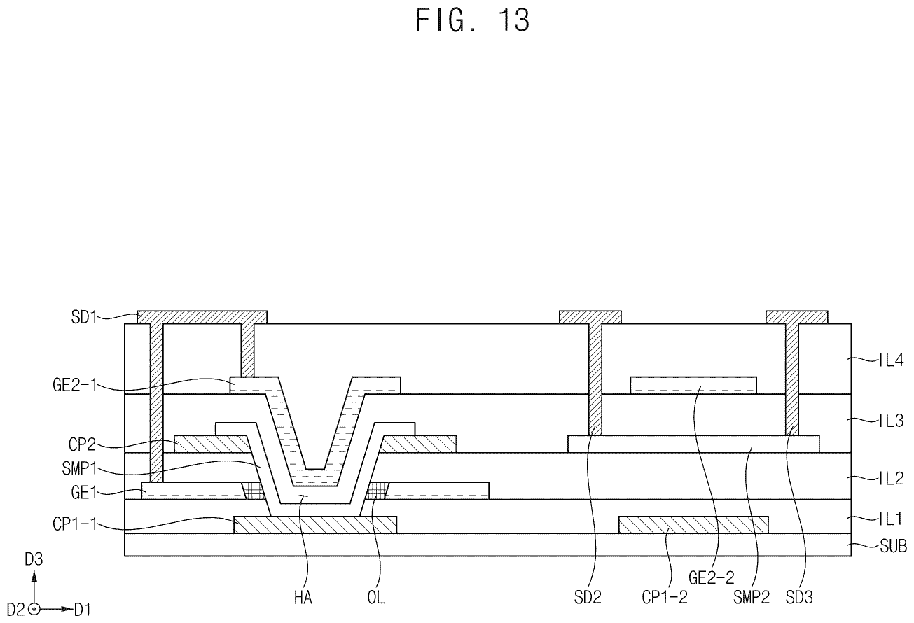

Referring further to FIG. 13, the first, second, and third interlayer conductive layers SD1, SD2, and SD3 may be formed in the holes. As shown in FIG. 13, the first, second, and third interlayer conductive layers SD1, SD2, and SD3 may be formed to extend in a direction opposite to the third direction D3. The first interlayer conductive layer SD1 may be formed while contacting the first gate electrode GE1 and the second-first gate electrode GE2-1. Each of the second and third interlayer conductive layers SD2 and SD3 may be formed while contacting the second semiconductor pattern SMP2.

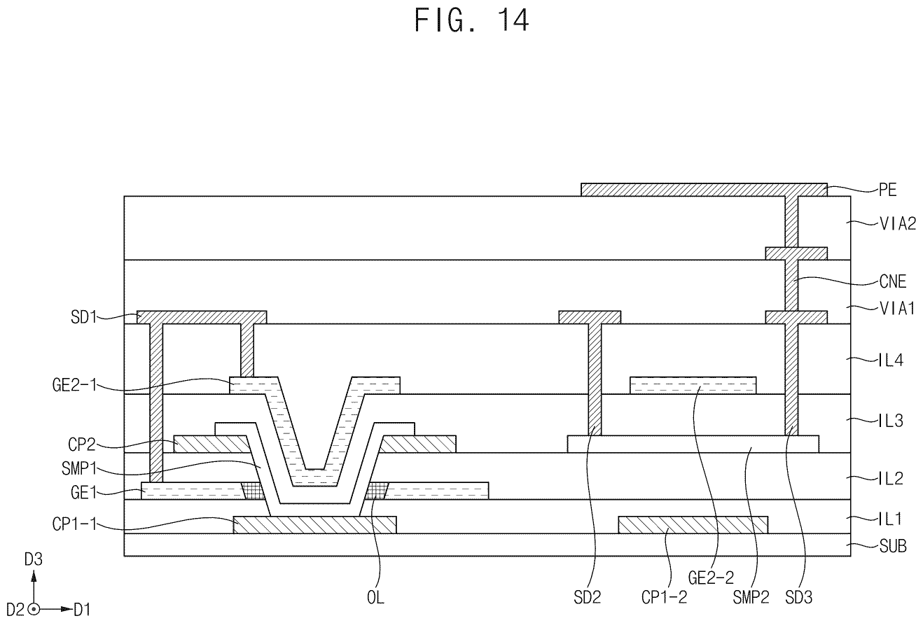

Referring further to FIG. 14, the first via layer VIA1, the connection electrode CNE, the second via layer VIA2, and the pixel electrode PE may be sequentially formed on the fourth insulating layer IL4. Thereafter, the components may be sequentially formed to complete the display panel DP of FIG. 3.

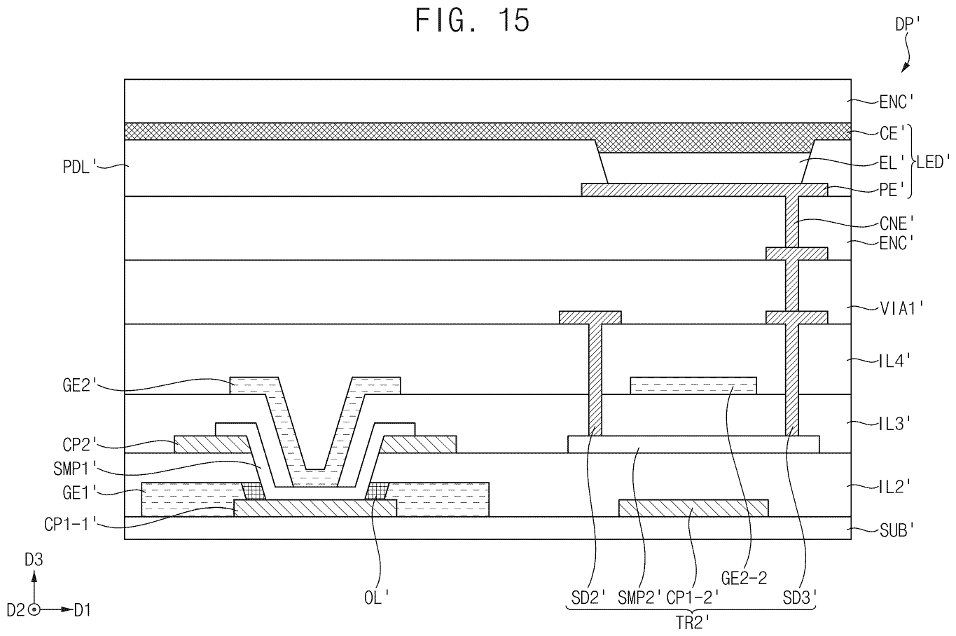

FIG. 15 is a cross-sectional view showing aspects of the display panel of FIG. 2 according to some embodiments. For example, FIG. 15 may be the same (or substantially the same) as FIG. 3 except that the first gate electrode GE1 and the first-first conductive pattern CP1-1 of FIG. 3 are not in contact, and the first interlayer conductive layer (e.g., the first interlayer conductive layer SD1 of FIG. 3) is omitted. Therefore, some redundant descriptions may be omitted or simplified.

Referring further to FIGS. 2, 3, and 15, the display panel DP′ may include a substrate SUB′, a first-second conductive pattern CP1-2′, second, third, and fourth insulating layers IL2′, IL3′, and IL4′, a first transistor TR1′, a second transistor TR2′, first, second, and third interlayer conductive layers SD1′, SD2′, and SD3′, a first via layer VIA1′, a connection electrode CNE′, a second via layer VIA2′, a light-emitting diode LED′, a pixel defining layer PDL′, and an encapsulation layer ENC′.

The first transistor TR1′ may include a first-first conductive pattern CP1-1′, a second conductive pattern CP2′, a first semiconductor pattern SMP1′, a first gate electrode GE1′, and a second-first gate electrode GE2-1′. The second transistor TR2′ may include a second semiconductor pattern SMP2′ and a second-second gate electrode GE2-2′. The light-emitting diode LED′ may include a pixel electrode PE′, an emission layer EL′, and a common electrode CE′.

The first-first conductive pattern CP1-1′ and the first-second conductive pattern CP1-2′ may be located on the substrate SUB′.

The first gate electrode GE1′ may be located on the first-first conductive pattern CP1-1′. The first gate electrode GE1′ may be located in direct contact with the first-first conductive pattern CP1-1′. Accordingly, the first-first conductive pattern CP1-1′ and the first gate electrode GE1′ may be electrically connected. When the first-first conductive pattern CP1-1′ and the first gate electrode GE1′ are connected, current may be stably controlled. In this case, the first transistor TR1′ may be a driving transistor.

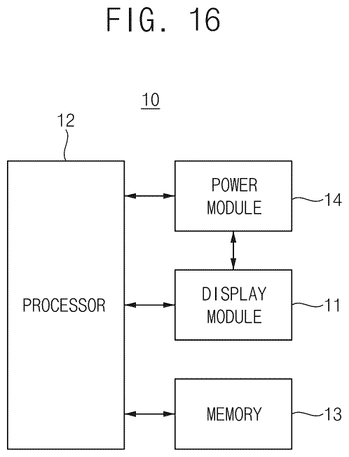

FIG. 16 is a block diagram showing an electronic device according to some embodiments of the present disclosure.

Referring to FIGS. 1 and 16, the display device DD according to embodiments of the present disclosure may be applied to various electronic devices 10. An electronic device 10 according to some embodiments may include the display device DD and additional modules or devices providing other functionalities.

The electronic device 10 may include a display module 11, a processor 12, a memory 13, and a power module 14.

The processor 12 may include at least one of a central processing unit CPU, an application processor AP, a graphics processing unit GPU, a communication processor CP, an image signal processor ISP, or a controller.

The memory 13 may store data and information required for the operation of the processor 12 or the display module 11. When the processor 12 executes an application stored in the memory 13, video data signals and/or input control signals may be transmitted to the display module 11. The display module 11 may process the received signals to output video information on the display screen.

The power module 14 may include a power adapter, a battery device, and a power conversion module for generating the power required for the operation of the electronic device 10.

At least one component of the electronic device 10 described above may be included in the display device according to the embodiments of the present disclosure. Some individual components functionally included in a module may be integrated into the display device, while others may be provided separately from the display device. For example, the display device DD may include the display module 11, while the processor 12, the memory 13, and the power module 14 may be provided as separate devices within the electronic device 10.

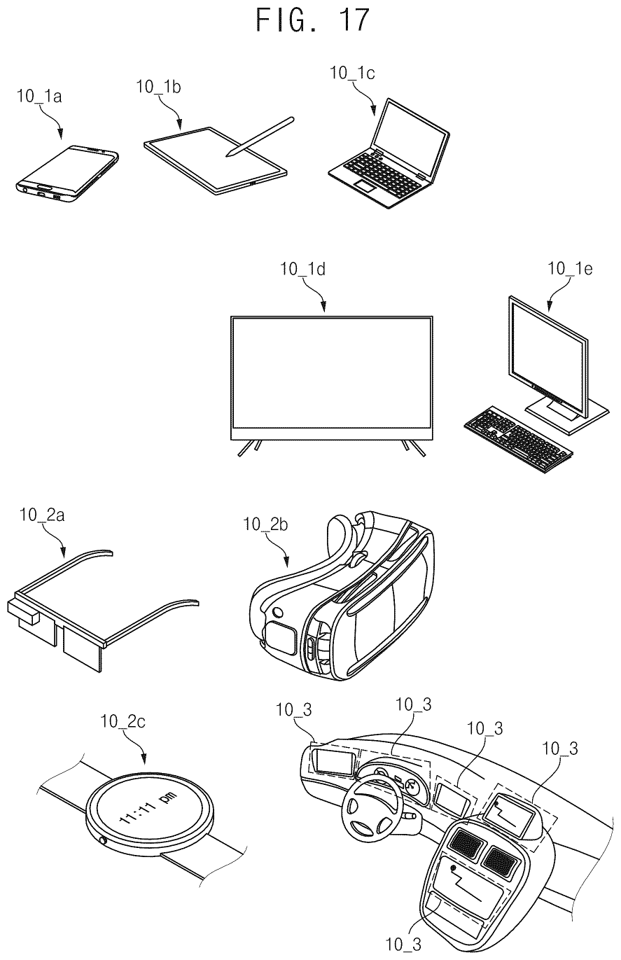

FIG. 17 is schematic diagrams showing various embodiments of the electronic device of FIG. 16.

Referring to FIGS. 16 and 17, various electronic devices 10 incorporating the display device DD may include image-display electronic devices such as smartphones 10_1a, tablet PCs 10_1b, laptops 10_1c, TVs 10_1d, and desktop monitors 10_1e. In addition, wearable electronic devices including display modules, such as smart glasses 10_2a, head-mounted displays 10_2b, and smartwatches 10_2c, and vehicle electronic devices including display modules, such as instrument clusters, center information displays (CID), and room mirror displays, may also be included.

However, these examples are illustrative, and the electronic device 10 according to the embodiments of the present disclosure are not necessarily limited thereto. For example, the electronic device 10 may be implemented as a mobile phone, videophone, smart pad, smartwatch, tablet PC, vehicle display, computer monitor, laptop, or head-mounted display device. In addition, the electronic device 10 may be a television, monitor, laptop computer, or tablet. Furthermore, the electronic device 10 may also be a vehicle.

While aspects of some embodiments of the present disclosure have been particularly shown and described with reference to embodiments thereof, it will be understood by those of ordinary skill in the art that various changes in form and details may be made therein without departing from the spirit or scope of embodiments according to the present disclosure as defined by the following claims, and their equivalents.

What is claimed is:

1. A display device comprising:
a substrate;
a first conductive pattern on the substrate;
a first gate electrode on the first conductive pattern;
a second conductive pattern on the first gate electrode;
a semiconductor pattern on the second conductive pattern, extending along a hole area penetrating the first gate electrode and the second conductive pattern in a first direction, which is a thickness direction, and electrically connected to the first conductive pattern and the second conductive pattern;
a metal oxide pattern between the first gate electrode and the semiconductor pattern and insulating between the first gate electrode and the semiconductor pattern; and
a second gate electrode on the semiconductor pattern, extending along the hole area, and electrically connected to the first gate electrode.

2. The display device of claim 1, further comprising:
a first insulating layer that insulates the first conductive pattern and the first gate electrode; and
a second insulating layer that insulates the first gate electrode and the second conductive pattern.

3. The display device of claim 2, wherein a thickness of each of the first insulating layer and the second insulating layer between the first gate electrode and the first conductive pattern is 1 nm to 1 μm.

4. The display device of claim 1, wherein a thickness of the metal oxide pattern in a second direction intersecting the first direction is 1 nm to 1 μm.

5. The display device of claim 1, wherein the hole area exposes an upper surface of the first conductive pattern.

6. The display device of claim 1, wherein the second conductive pattern includes a conductive oxide.

7. The display device of claim 1, wherein the first gate electrode includes at least one selected from a group including aluminum and titanium.

8. The display device of claim 1, wherein the semiconductor pattern includes an oxide semiconductor.

9. A display device comprising:
a substrate;
a first conductive pattern on the substrate;
a first gate electrode on the first conductive pattern and electrically connected to the first conductive pattern;
a second conductive pattern on the first gate electrode;
a semiconductor pattern on the second conductive pattern, extending along a hole area penetrating the first gate electrode and the second conductive pattern in a first direction which is a thickness direction, and electrically connected to the first conductive pattern and the second conductive pattern;
a metal oxide pattern between the first gate electrode and the semiconductor pattern and insulating between the first gate electrode and the semiconductor pattern; and
a second gate electrode on the semiconductor pattern and extending along the hole area.

10. The display device of claim 9, further comprising an insulating layer insulating the first gate electrode from the second conductive pattern.

11. The display device of claim 10, wherein a thickness of the insulating layer between the first gate electrode and the first conductive pattern is 1 nm to 1 μm.

12. The display device of claim 9, wherein a thickness of the metal oxide pattern in a second direction intersecting the first direction is 1 nm to 1 μm.

13. The display device of claim 9, wherein the hole area exposes an upper surface of the first conductive pattern.

14. The display device of claim 9, wherein the second conductive pattern includes a conductive oxide.

15. The display device of claim 9, wherein the first gate electrode includes at least one selected from a group including aluminum and titanium.

16. The display device of claim 9, wherein the semiconductor pattern includes an oxide semiconductor.

17. An electronic device comprising:
a display device; and
a processor configured to drive the display device, and
wherein the display device includes
a substrate;
a first conductive pattern on the substrate;
a first gate electrode on the first conductive pattern;
a second conductive pattern on the first gate electrode;
a semiconductor pattern on the second conductive pattern, extending along a hole area penetrating the first gate electrode and the second conductive pattern in a first direction, which is a thickness direction, and electrically connected to the first conductive pattern and the second conductive pattern;
a metal oxide pattern between the first gate electrode and the semiconductor pattern and insulating between the first gate electrode and the semiconductor pattern; and
a second gate electrode on the semiconductor pattern, extending along the hole area, and electrically connected to the first gate electrode.
